(19) United States
(12) Patent Application Publication
(10) Pub. No.: US 2008/0314320 A1
(43) Pub. Date: Dec. 25, 2008

(54) Chamber Mount for High Temperature Application of AIN Heaters

(75) Inventors: Frank Balma, Monte Sereno, CA (US); Brent Elliot, Cupertino, CA (US); Alexander Veytser, Mountain View, CA (US)

Correspondence Address: CARR & FERRELL LLP, 2200 GENG ROAD, PALO ALTO, CA, 94303, US

(73) Assignee: Component Re-Engineering Company, Inc.

(21) Appl. No.: 12/151,427

(22) Filed: May 5, 2008

Related U.S. Application Data
(62) Division of application No. 11/346,660, filed on Feb. 3, 2006.
(60) Provisional application No. 60/650,067, filed on Feb. 4, 2005.

(51) Int. Cl. H01L 21/30; C23C 16/54

(52) U.S. Cl. 118/728

(57) ABSTRACT

A susceptor for high temperature semiconductor processing is provided. The susceptor includes a substrate support joined to a hollow shaft having a pair of ports to allow an inert gas to be purged through an internal volume of the shaft. Some embodiments of the susceptor include a chamber mount to support the shaft within a processing chamber and a chamber mount insert disposed within the chamber mount. In these embodiments the chamber mount insert includes the ports. The chamber mount insert can also include a thermocouple tube with a fitting to seal around the thermocouple and to impart an upward pressure to the thermocouple to keep the thermocouple properly seated within the substrate support. The chamber mount insert can also include electrical connectors with glass-to-metal seals.

### CROSS-REFERENCE TO RELATED APPLICATIONS

This application is a divisional and claims the priority benefit of U.S. patent application Ser. No. 11/346,660, filed Feb. 3, 2006 and entitled “Chamber Mount for High Temperature Application of AlN Heaters,” which claims the priority benefit of U.S. Provisional Patent Application Ser. No. 60/650,067, filed Feb. 4, 2005 and entitled “Chamber Mount for High Temperature Application of AlN Heaters;” the disclosures of the aforementioned applications are incorporated herein by reference in its entirety.

### BACKGROUND OF THE INVENTION

1. Field of the Invention

The present invention relates generally to the field of semiconductor fabrication, and more particularly to a chamber mount for supporting a susceptor in a processing chamber.

2. Description of Related Art

Semiconductor processing and similar manufacturing processes typically employ thin film deposition techniques such as Chemical Vapor Deposition (CVD). In CVD processing, as well as in similar manufacturing techniques, a substrate such as a silicon wafer is secured within a processing chamber by a susceptor and exposed to the particular processing conditions of the process. The susceptor is essentially a pedestal that, in addition to securing the substrate, can in some instances also be used to heat the substrate.

FIG. 1 illustrates a cross-section of a susceptor 100, according to the prior art, set inside a processing chamber 110, such as a CVD chamber. The susceptor 100 includes a substrate support 120 joined to a support shaft 130, and conductors 140 (only one shown for simplicity) extending from the substrate support 120 through the support shaft 130.

The substrate support 120 comprises an insulating body 150, a conductive element 160 disposed within the insulating body 150, and related components such as bushings. The insulating body 150 can be formed, for example, of a ceramic such as AlN. The conductive element 160 can comprise, for instance, a heating element, an RF grid, or an electrostatic electrode. Other components can be formed, for example, of materials such as molybdenum, tungsten, or other conductive materials of similar coefficient of thermal expansion (CTE) as the insulating body 150.

In a typical semiconductor fabrication apparatus, the conductive element 160 comprises a heater to accelerate chemical reactions during semiconductor fabrication. In some apparatus, the inside of the support shaft 130 is open to the atmosphere outside of the chamber 110 and accordingly, at high processing temperatures, for example, above 650° C., oxidation of metal susceptor components and brazed connections can occur, causing poor quality in the produced semiconductors, and premature failure of the susceptor.

One solution has been to pull a vacuum within the support shaft 130. However, this solution is not ideal. Maintaining the support shaft 130 under vacuum has been found to slow the rate of oxidation but does not stop the oxidation of metal components exposed to the atmosphere within the support shaft 130. This approach also adds complexity and cost, and has been found to reduce thermocouple reading accuracy.

Therefore, what is needed is a susceptor that better resists oxidation of metal components during high-temperature operation of the heater portion of the susceptor.

### SUMMARY OF THE INVENTION

An exemplary embodiment of the present invention comprises a susceptor including a substrate support configured to support a substrate and a support shaft, including an internal volume, joined to the substrate support. The susceptor also includes a chamber mount, optionally water cooled, for mounting the support shaft within a chamber, and a chamber mount insert disposed within the chamber mount. The chamber mount insert includes a gas inlet port and a gas outlet port both in fluid communication with the internal volume of the support shaft. Some embodiments of the susceptor include a flow restrictor, such as a sintered metal flow restrictor, disposed on the gas outlet port. The flow restrictor is configured, in some embodiments, to limit a gas flow rate through the support shaft to about 150 sccm at about 1.5 psig supply pressure.

The chamber mount insert, in some embodiments, includes electrical connectors for connecting electrical conductors within the support shaft with external power supplies. A glass seal-electrically insulates the electrical connectors from the chamber mount insert. Additionally, the chamber mount insert can include a thermocouple tube with a fitting. A thermocouple fitted into the substrate support is disposed through the chamber mount and through the thermocouple tube of the chamber mount insert. The fitting is configured to seal around the thermocouple. In some embodiments, the fitting is further configured to impart an upward pressure against the thermocouple to keep the thermocouple properly seated within the substrate support.

Another exemplary embodiment of the present invention comprises a semiconductor processing system including a processing chamber and a susceptor of the invention. The system also can include an inert gas source coupled to the gas inlet port of the susceptor. In some embodiments, the inert gas source comprises nitrogen.

### BRIEF DESCRIPTION OF THE DRAWINGS

FIG. 1 illustrates a cross-section of a susceptor according to an embodiment of the prior art.

FIG. 2 illustrates a cross-section view of a susceptor according to an exemplary embodiment of the invention. FIG. 3 illustrates an expanded perspective view of a susceptor, according to another exemplary embodiment of the invention.

FIG. 4 illustrates a side and partial cross-section view of the embodiment shown in FIG. 3.

FIG. 5 illustrates an expanded side view of a chamber mount insert, according to an exemplary embodiment of the invention.

FIG. 6 illustrates a cross-section view of a chamber mount insert, according to an exemplary embodiment of the invention.

### DETAILED DESCRIPTION

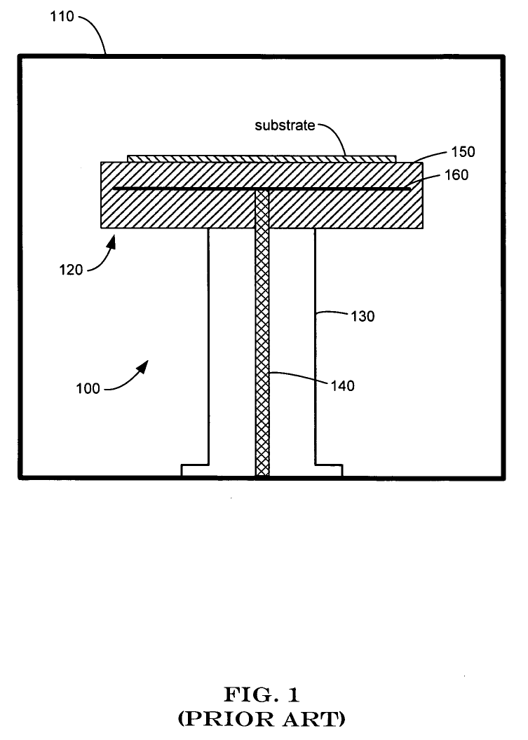

The present invention provides a simple means for purging an internal volume of the support shaft 130 (FIG. 1) with an inert gas. The inert gas flow rate is controlled so that the rate is sufficient to prevent oxidation, but low enough to prevent unwanted cooling of the substrate support 120 (FIG. 1) in the vicinity of the support shaft 130. Embodiments of the invention include two ports for allowing gas flow through the support shaft 130, and further embodiments include a flow restrictor in line with one of the ports to limit the flow rate. Embodiments of the invention can comprise a chamber mount and a chamber mount insert that include the ports and provide additional advantages, as described below.

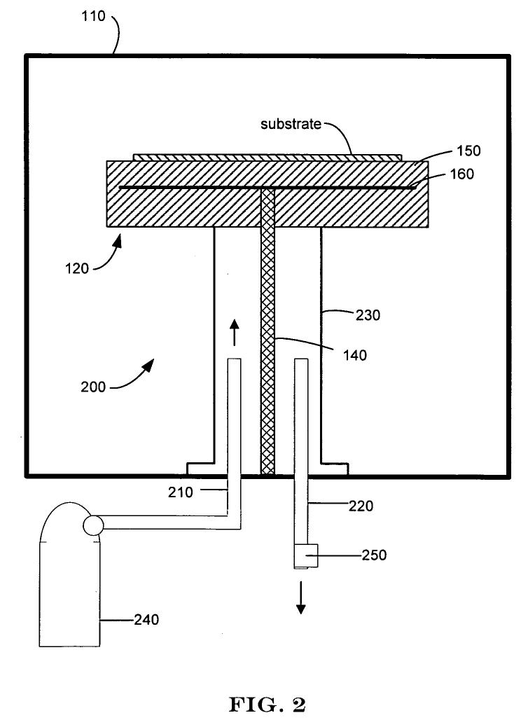

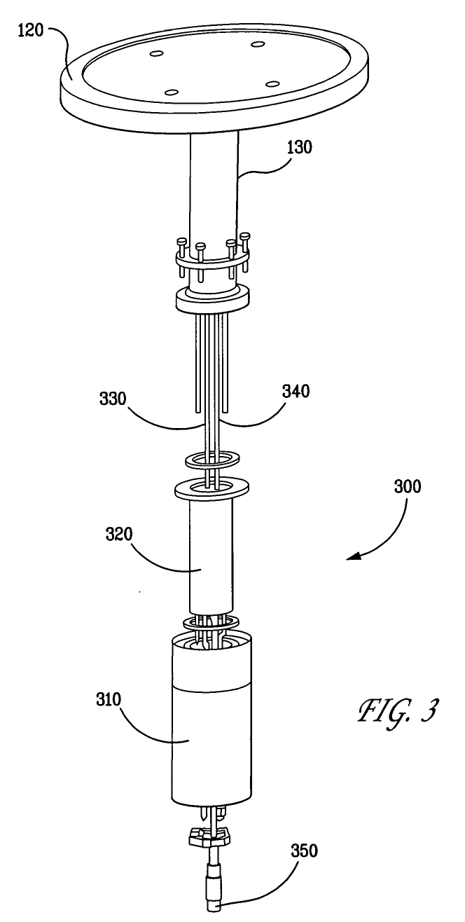

FIG. 2 illustrates a cross-section of a susceptor 200 according to an exemplary embodiment of the invention. Inlet port 210 and outlet port 220 extend into the support shaft 230 from the outside of the processing chamber 110. Inlet port 210 is coupled to a source 240 of an inert gas, such as a gas cylinder. Suitable inert gases include nitrogen, helium, and argon. Outlet port 220 is optionally coupled to a flow restrictor 250. The flow restrictor 250 is configured to control the flow of the inert gas through the support shaft 230. The flow of inert gas purges oxygen from support shaft 230, thus reducing the amount of oxygen present during operation of the heating element 160, thereby decreasing oxidation of metal components within the support shaft 230.

In an exemplary embodiment, the flow restrictor 250 comprises a sintered-metal flow restrictor. In some embodiments, the flow restrictor 250 is configured to control inert gas flow to about 150 standard cubic centimeters per minute (sccm) at about 1.5 pounds per square inch gauge (psig) supply pressure. In further embodiments, the flow from the outlet port 220 is restricted to at least 100 sccm. In some embodiments, the inert gas input is at a pressure of about 1 psig. It will be appreciated that the flow restrictor 250 can alternately be located on the input port 210. Other means for regulating the inert gas flow can also be implemented.

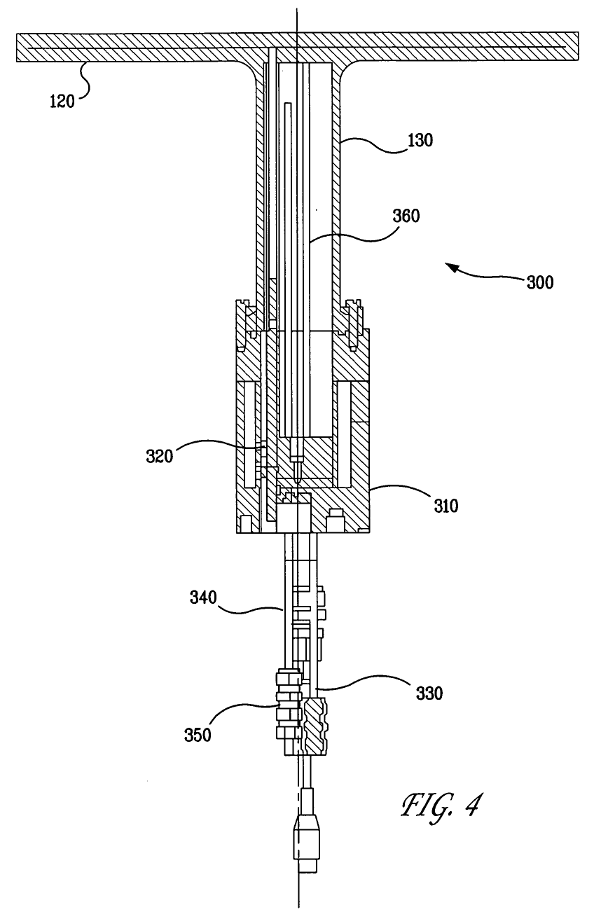

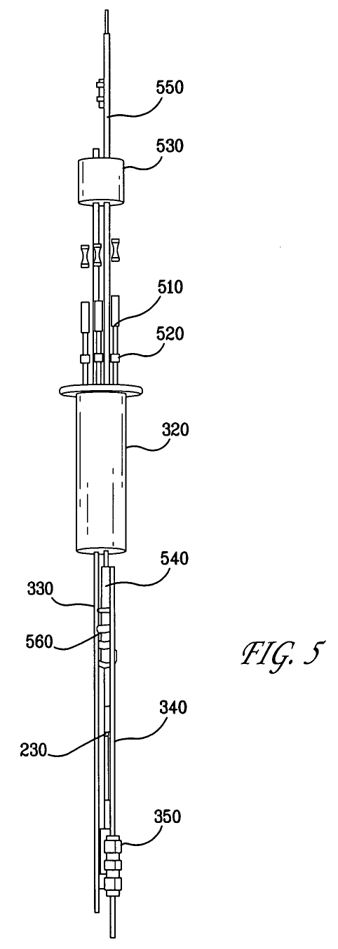

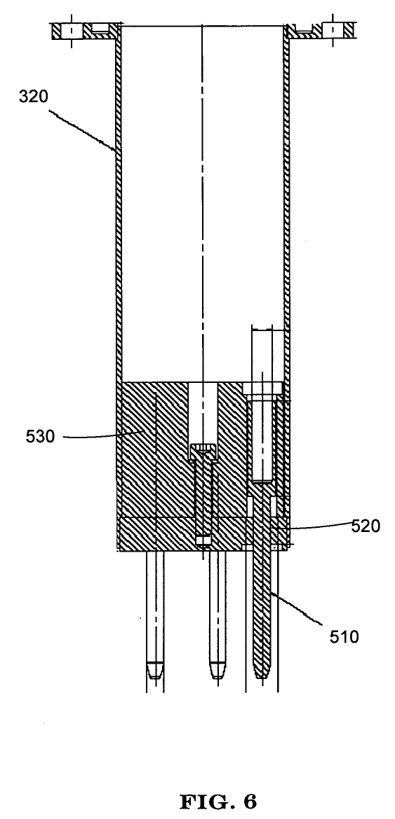

FIGS. 3 and 4, respectively, illustrate an expanded perspective view and a side and partial cross-section view of a susceptor 300 according to one exemplary embodiment of the invention. The susceptor 300 comprises a substrate support 120, a support shaft 130, a chamber mount 310, and a chamber mount insert 320. As described below with reference to FIGS. 5 and 6, the chamber mount insert 320 includes an inlet port 330, an outlet port 340, and a flow restrictor 350 coupled to the outlet port 340. Susceptor 300 also comprises a thermocouple 360 disposed through the chamber mount 310 and chamber mount insert 320, as described below with reference to FIGS. 5 and 6.

Chamber mount 310 is configured to mount to the inside of the chamber 110 and to support the susceptor 300. The chamber mount insert 320 is disposed within, and sealed against, the chamber mount 310, as can be seen in FIG. 4. In some embodiments, the chamber mount 310 is water cooled. For simplicity, and because water cooling is well known, the water lines to the chamber mount 310 are omitted from FIGS. 3 and 4.

FIGS. 5 and 6 illustrate, respectively, a side view and a cross-section view of a chamber mount insert 320, according to an exemplary embodiment of the invention. Ports 330 and 340 (not shown in FIG. 6) extend into the chamber mount insert 320 and can be welded thereto. The chamber mount insert 320 also includes electrical connectors 510 to electrically connect to electrical components within the support shaft 130 such as conductors 140 (FIG. 1) to external power sources. In some embodiments, glass compression seals 520 are employed to both seal the electrical connectors 510 to the bottom of the chamber mount insert 320 and to insulate the electrical connectors 510 from the chamber mount insert 320. A further insulator 530, made of a material such as alumina, provides insulation between the electrical connectors 510 and the chamber mount insert 320 within the chamber mount insert 320.

The chamber mount insert 320 also comprises a thermocouple tube 540 (not shown in FIG. 6) that may be welded to the chamber mount insert 320 through which a thermocouple 550 (not shown in FIG. 6) is disposed. The thermocouple 550 extends into the substrate support 120 (FIG. 1) to measure the temperature of the substrate support 120 during processing.

As the thermocouple 550 heats and cools it is subject to considerable expansion and contraction that should be accommodated by the chamber mount insert 320. Accordingly, the thermocouple tube 540 includes a fitting 560 that both seals the end of the thermocouple tube 540 around the thermocouple 550 and maintains an upward pressure on the thermocouple 550. The upward pressure can be provided by a spring mechanism, for example, within the fitting 560. The upward pressure serves to keep the thermocouple 550 snugly fit into the substrate support 120. It has been found that the thermocouple 550 has a tendency to pull away from the substrate support 120 with repeated thermal cycles without the upward pressure.

In the foregoing specification, the invention is described with reference to specific embodiments thereof, but those skilled in the art will recognized that the invention is not limited thereto. Various features and aspects of the above-described invention may be used individually or jointly. Further, the invention can be utilized in any number of environments and applications beyond those described herein without departing from the broader spirit and scope of the specification. The specification and drawings are accordingly, to be regarded as illustrative rather than restrictive. It will be recognized that the terms “comprising,” “including,” and “having,” as used herein, are specifically intended to be read as open-ended terms of art.

What is claimed is:

1. A susceptor comprising:
a substrate support configured to support a substrate;
a support shaft, including an internal volume, joined to the substrate support;
a chamber mount for mounting the support shaft within a chamber; and
a chamber mount insert disposed within the chamber mount and including a gas inlet port and a gas outlet port both in fluid communication with the internal volume of the support shaft.

2. The susceptor of claim 1 further comprising a flow restrictor coupled to the gas outlet port.

3. The susceptor of claim 2, wherein the flow restrictor comprises a sintered-metal piece.

4. The susceptor of claim 2, wherein the flow restrictor is configured to limit a gas flow rate through the support shaft to about 150 sccm at about 1.5 psig supply pressure.

5. The susceptor of claim 1, wherein the chamber mount insert further comprises an electrical connector and a glass seal between the electrical connector and the chamber mount insert.

6. The susceptor of claim 1 further comprising a thermocouple fit into the substrate support and disposed through the chamber mount, wherein the chamber mount insert further includes a thermocouple tube joined thereto and disposed around the thermocouple and including a fitting configured to seal around the thermocouple.

7. The susceptor of claim 6, wherein the fitting is further configured to impart an upward pressure against the thermocouple.

8. The susceptor of claim 1, wherein the chamber mount is water cooled.

9. A semiconductor processing system comprising:
a processing chamber; and
a susceptor disposed within the processing chamber and including
a substrate support configured to support a substrate,
a support shaft, having an internal volume, joined to the substrate support,
a chamber mount supporting the support shaft within the processing chamber, and
a chamber mount insert disposed within the chamber mount and including a gas inlet port and a gas outlet port both in fluid communication with the internal volume of the support shaft.

10. The semiconductor processing system of claim 9 further comprising an inert gas source coupled to the gas inlet port.

11. The semiconductor processing system of claim 10 wherein the inert gas source comprises nitrogen.
